(19) United States
(12) Patent Application Publication
(10) Pub. No.: US 2008/0169468 A1
(43) Pub. Date: Jul. 17, 2008

(54) Method and Apparatus For Fabricating Polycrystalline Silicon Film Using Transparent Substrate

(75) Inventor: Bum Mo Ahn, Gyeonggi-do (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: POINT ENGINEERING CO., LTD, Hwaseong-si,Gyeonggi-do (KR)

(21) Appl. No.: 11/908,584

(22) PCT Filed: Nov. 14, 2006
(86) PCT No.: PCT/KR2006/004768

§ 371 Date: Sep. 13, 2007

(30) Foreign Application Priority Data
Dec. 26, 2005 (KR) 10-2005-0129620

(51) Int. Cl. H01L 29/04; H01L 21/205; H01L 21/336; C23C 16/00

(52) U.S. Cl. 257/49; 438/488; 118/725; 438/151; 257/E21.103; 257/E29.003; 257/E21.412

(57) ABSTRACT

Provided is a method and apparatus for fabricating a polycrystalline silicon film using a transparent substrate. The method includes forming a light absorption layer on a surface of the transparent substrate; and heating the light absorption layer using irradiation of Rapid Thermal Process (RTP) light source, while depositing the polycrystalline silicon film on the light absorption layer.

### TECHNICAL FIELD

The present invention relates to a method and apparatus for fabricating a polycrystalline silicon film, and a structure thereof, and more particularly, to a method and apparatus for fabricating a polycrystalline silicon film using a transparent substrate, for providing an excellent electrical characteristic by using a Rapid Thermal Process (RTP) light source as, not a heat treatment source, an energy source for depositing polycrystalline silicon by an RTP and a Chemical Vapor Deposition (CVD).

### BACKGROUND ART

Polycrystalline silicon (Poly-Si) is being applied to various electronic devices, e.g. a Thin Film Transistor (TFT) device as well as a solar cell because it has an excellent electrical characteristic compared with amorphous silicon (a-Si). In general, a polycrystalline silicon electronic device formed using a silicon or quartz substrate has a disadvantage that material is expensive. In consideration of the disadvantage, a transparent substrate of cheap glass or plastic has been proposed. However, the transparent substrate has a critical disadvantage that it is vulnerable to a high temperature process (600° C. or more). Accordingly, a thermal damage or deformation of the substrate is frequently caused.

As a method for fabricating the polycrystalline silicon, there are an amorphous silicon poly-crystallization method for forming and then, crystallizing an amorphous silicon film by an optical energy such as a laser or a thermal energy, and a vapor deposition method for directly depositing the polycrystalline silicon film on a substrate by Low Temperature Poly Silicon-Plasma Enhanced Chemical Vapor Deposition (LTPS-PECVD).

However, the amorphous silicon poly-crystallization method necessarily includes a subsequent heat treatment process using a laser irradiation or an RTP. Therefore, the amorphous silicon poly-crystallization method has a drawback that a yield is low and a crystallization time is long taken. The vapor deposition method cannot use the transparent substrate of the cheap glass or plastic having a low softening temperature, because the polycrystalline silicon film should be deposited at a high temperature of 600° C. or more. Therefore, the vapor deposition method is disadvantageous in cost aspect.

### DISCLOSURE OF INVENTION

### Technical Problem

Accordingly, the present invention is directed to a method and apparatus for fabricating a polycrystalline silicon film using a transparent substrate that substantially overcomes one or more of the limitations and disadvantages of the conventional art.

One object of the present invention is to fabricate a polycrystalline silicon film having an excellent electrical characteristic by using a Rapid Thermal Process (RTP) light source as, not a heat treatment source, an energy source for depositing polycrystalline silicon by an RTP and a Chemical Vapor Deposition (CVD).

Another object of the present invention is to increase a surface efficiency of a transparent substrate based on light energy by a light absorption layer, and provide backside cooling by a substrate holder, thereby overcoming a vulnerability of the transparent substrate originating from a high temperature process.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims as well as the appended drawings.

### Technical Solution

To achieve the above and other objects and advantages, and in accordance with the purpose of the invention, as embodied and broadly described herein, there is provided a method for fabricating a polycrystalline silicon film using a transparent substrate. The method includes forming a light absorption layer on a surface of the transparent substrate; and heating the light absorption layer using irradiation of Rapid Thermal Process (RTP) light source, while depositing the polycrystalline silicon film on the light absorption layer.

In another aspect of the present invention, there is provided an apparatus for forming a polycrystalline silicon film on a surface of a transparent substrate. The apparatus includes a substrate holder provided within a reaction furnace, and holding the transparent substrate and performing backside cooling for the transparent substrate; the transparent substrate having a light absorption layer and loaded on the substrate holder; and an RTP light source for heating the light absorption layer, and providing a reaction energy for forming the polycrystalline silicon film.

In a further another aspect of the present invention, there is provided a method for fabricating a Thin Film Transistor (TFT) having a transparent substrate, a polycrystalline silicon active layer formed on the transparent substrate, a gate insulating layer formed on the polycrystalline silicon active layer, and a gate formed on the gate insulating layer. The forming of the polycrystalline silicon active layer further includes forming a light absorption layer on a surface of the transparent substrate; and heating the light absorption layer using irradiation of a Rapid Thermal Process (RTP) light source, while depositing a polycrystalline silicon film on the light absorption layer.

In a yet another aspect of the present invention, there is provided a method for fabricating a Field Effect Transistor (FET) having a transparent substrate, a polycrystalline silicon active layer formed on the transparent substrate, a gate insulating layer formed on the polycrystalline silicon active layer, and a gate formed on the gate insulating layer. The forming of the polycrystalline silicon active layer further includes forming a light absorption layer on a surface of the transparent substrate; and heating the light absorption layer using irradiation of an RTP light source, while depositing a polycrystalline silicon film on the light absorption layer.

In a still another aspect of the present invention, there is provided a structure of a polycrystalline silicon film using a transparent substrate. The structure includes a light absorption layer formed on the transparent substrate; and the polycrystalline silicon film formed on the light absorption layer while heating the light absorption layer using irradiation of an RTP light source.

The light absorption layer may be of any one selected from the groups consisting of silicon (Si), amorphous silicon (a-Si), germanium (Ge), silicon carbide (SiC), amorphous carbon (a-C), gallium arsenide (GaAs), silicon germanium (SiGe), and III-V group compound semiconductor material.

It is to be understood that both the foregoing summary and the following detailed description of the present invention are merely exemplary and intended for explanatory purposes only.

### BRIEF DESCRIPTION OF THE DRAWINGS

The accompanying drawings, which are included to aid in understanding the invention and are incorporated into and constitute a part of this application, illustrate embodiment(s) of the invention and together with the description serve to explain the principles of the invention. In the drawings:

FIGS. 1 and 2 are process diagrams illustrating a method for fabricating a polycrystalline silicon film using a transparent substrate according to the present invention;

FIG. 3 is a diagram illustrating a state in which a transparent substrate is safely mounted on a substrate holder in a method for fabricating a polycrystalline silicon film using the transparent substrate according to the present invention;

FIG. 4 is a plan view illustrating a substrate holder according to the present invention;

FIG. 5 is a diagram illustrating a distribution of a grain size of conventional polycrystalline silicon;

FIG. 6 is a diagram illustrating a distribution of a grain size of polycrystalline silicon according to the present invention;

FIG. 7 is a cross section schematically illustrating a Thin Film Transistor (TFT) according to the present invention;

FIG. 8 is a cross section schematically illustrating a Field Effect Transistor (FET) according to the present invention; and

FIG. 9 is a cross section illustrating a structure of a polycrystalline silicon film using a transparent substrate according to the present invention.

### BEST MODE FOR CARRYING OUT THE INVENTION

Reference will now be made in detail to the preferred embodiments of the present invention, examples of which are illustrated in the accompanying drawings. Wherever possible, the same reference numerals will be used throughout the drawings to refer to the same or like parts.

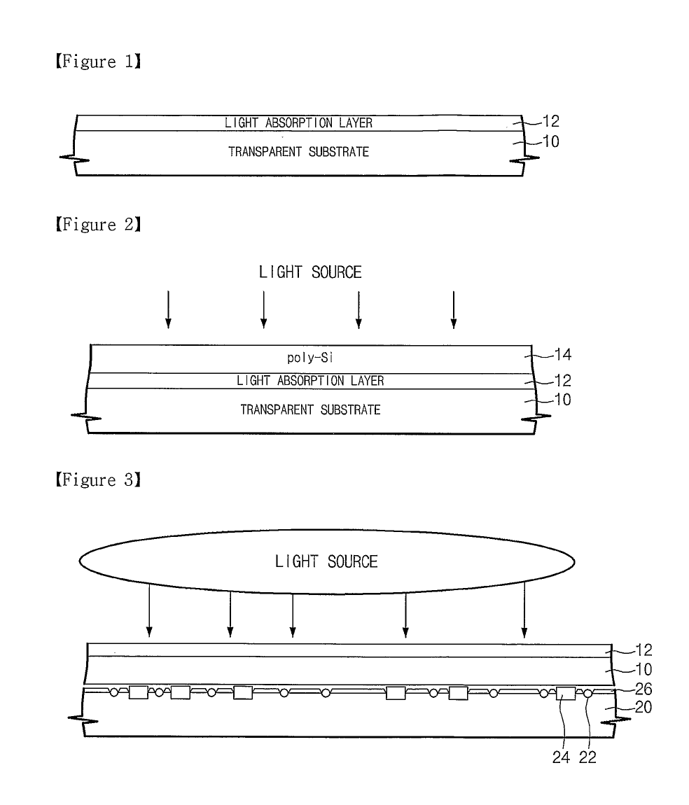

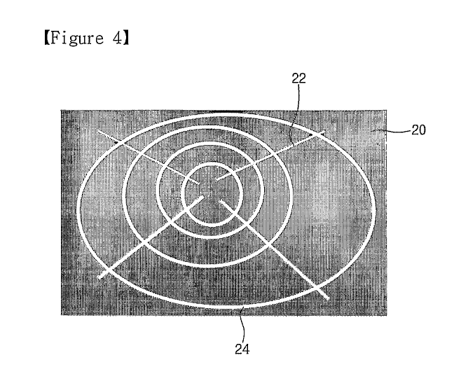

FIGS. 1 and 2 are process diagrams illustrating a method for fabricating a polycrystalline silicon film using a transparent substrate according to the present invention. FIG. 3 is a diagram illustrating a state in which the transparent substrate is safely mounted on a substrate holder in the method for fabricating the polycrystalline silicon film using the transparent substrate according to the present invention. FIG. 4 is a plan view illustrating the substrate holder according to the present invention.

As shown in FIG. 1, a light absorption layer 12 is deposited on the transparent substrate 10 at about 500° C. or less using a low temperature Plasma Enhanced Chemical Vapor Deposition (PECVD) and a thermal Chemical Vapor Deposition (CVD).

The light absorption layer 12 suppresses a transmittance of light through the transparent substrate 10, thereby improving an efficiency of heating a substrate surface by a light source. In other words, the light absorption layer 12 supplies a surface energy by light absorption occurring on its surface, for a reaction for forming polycrystalline silicon.

The light absorption layer 12 is of material having a high extinction coefficient, for example, silicon (Si), amorphous silicon (a-Si), germanium (Ge), silicon carbide (SiC), amorphous carbon (a-C), gallium arsenide (GaAs), and silicon germanium (SiGe). The extinction coefficient is 0.01 or more based on visible rays having a wavelength of about 440 nm to 680 nm.

As shown next in FIG. 2, a reaction energy obtained by heating the light absorption layer 12 is provided using energy of a predetermined light source, while a precursor to be deposited, e.g. a silicon source gas is introduced into a reaction furnace, to form the polycrystalline silicon film 14 on the light absorption layer 12 at a predetermined thickness.

The light source can be a visible ray-based halogen lamp, ultraviolet rays, or a combination thereof. The light source can have a wavelength of about 150 nm to 2,000,000 nm. The light source is irradiated at an angle of about 10° to 170° about the substrate. In addition, a laser can be used as the light source.

In particular, the light source is an RTP light source applied to an RTP. In a conventional art, the RTP light source has been used only as a heat treatment source, but, in the present invention, the RTP light source is used as an energy source for depositing the polycrystalline silicon.

When the polycrystalline silicon film 14 is formed, the light absorption layer 12 is maintained at a spontaneous temperature within a range of about 450° C. to 1600° C. Here, the heated light absorption layer 12 provides the reaction energy necessary for forming the polycrystalline silicon film 14, to a silicon containing gas.

Referring to FIGS. 3 and 4, the present invention includes the substrate holder 20 for performing backside cooling for the transparent substrate 10. The substrate holder 20 includes a cooling channel 22 for increasing a backside cooling efficiency of the substrate; and a vacuum absorption channel 24 for preventing substrate deformation. The vacuum absorption channel 24 is not used in case where the substrate deformation is slight.

It is desirable that a reflective film 26 is coated on a top surface of the substrate holder 20. The reflective film 26 can reflect a part of light transmitting through the light absorption layer 12, again to the light absorption layer 12. The reflective film 26 is formed by surface-coating with material having a high reflection efficiency, e.g. gold.

While the polycrystalline silicon film 14 is formed on the light absorption layer 12 using the reaction energy that is obtained by heating the light absorption layer 12 formed on the transparent substrate 10, the substrate holder 20 cools the transparent substrate 10, and controls an increase of a temperature of the transparent substrate 10. It is desirable that the substrate holder 20 controls the backside cooling by selecting a temperature from a range of about −20° C. to a substrate deformation temperature, not causing a deformation and a thermal damage of the substrate, for effectively heating and cooling the substrate.

The cooling channel 22 is used for injecting gas having a high thermal conductivity between the substrate 10 and the substrate holder 20. The cooling channel 22 improves a thermal conductive efficiency, and a temperature uniformity of the entire substrate. The injection gas is a helium (He) gas having a high specific heat, and its pressure is within a range of about 0.1 Torr to 500 Torr.

The vacuum absorption channel 24 prevents the substrate from being deformed due to an increase of a stress that is caused by a temperature difference between a heated substrate surface and the substrate. A pressure of vacuum absorption is within a range of about 0.1 mTorr to 100 Torr.

As a chemical material for forming the polycrystalline silicon within the reaction furnace, there is a silicon (Si) or germanium (Ge) containing gas. For example, there are SiH₄, Si₂H₆, and DCS. Also, it is possible to form III-V group compound semiconductor material.

While the polycrystalline silicon is formed, in-situ doping can be performed using chemical material containing phosphorous (P), boron (B), and arsenic (As). For example, there are PH₃, B₂H₆, and BH₃.

An atmosphere gas is used for a uniform distribution of a silicon source gas. The atmosphere gas is hydrogen (H₂), argon (Ar), helium (He), and nitrogen (N₂).

It is desirable that a process pressure within the reaction furnace is maintained within a range of about 0.1 Torr to 1000 Torr.

While the polycrystalline silicon is deposited, a byproduct is generated and accumulated within the reaction furnace, and is a cause of contaminant particles. In order to remove the contaminant particles, a fluorine (F) gas is injected using a remote clean method. Also, a vapor of hydrogen fluoride (HF) can be injected to remove a contaminant deposited within the reaction furnace.

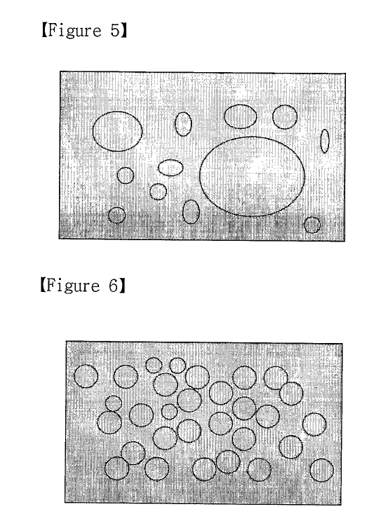

FIG. 5 is a diagram illustrating a distribution of a grain size of conventional polycrystalline silicon. FIG. 6 is a diagram illustrating a distribution of a grain size of the polycrystalline silicon according to the present invention.

It can be appreciated that the grain size of the polycrystalline silicon of FIG. 5 is very randomly distributed, but the grain size of the polycrystalline silicon of FIG. 6 is uniformly distributed.

The distribution of the grain size has a close relation with an electrical characteristic of the polycrystalline silicon. In case where the distribution of the grain size is random as shown in FIG. 5, the electrical characteristic of the polycrystalline silicon can vary depending on the grain size. Therefore, the grain size can have a bad influence on the reproducibility and the uniformity of a performance of a device within the substrate. On contrary, as shown in FIG. 6, the present invention can uniformly control the grain size by the light absorption layer, and obtain the uniform electrical characteristic of the device in the same substrate.

In other words, the present invention can uniformly control the grain size of the polycrystalline silicon by a structure of the light absorption layer, and obtain the uniform electrical characteristic of the device in the same substrate.

The method for fabricating the polycrystalline silicon film using the transparent substrate is of most importance in a method for fabricating a Thin Film Transistor (TFT), and other processes are well known in the art.

A feature of the method for fabricating the TFT according to the present invention is to provide the TFT having an excellent electrical characteristic without the damage or deformation of the substrate, by providing the reaction energy obtained by heating the light absorption layer formed on the transparent substrate while depositing the polycrystalline silicon.

FIG. 7 is a cross section schematically illustrating the TFT according to the present invention. The TFT includes the transparent substrate 10; the light absorption layer 12 formed on the transparent substrate 10; the polycrystalline silicon film 14 serving as a polycrystalline silicon active layer formed on the light absorption layer 12; a gate insulating layer formed on the polycrystalline silicon film 14; and a gate formed on the gate insulating layer.

The light absorption layer 12 is formed on a top surface of the transparent substrate 10. The polycrystalline silicon film 14 serving as the polycrystalline silicon active layer is formed on a top surface of the light absorption layer 12. The polycrystalline silicon film 14 is divided into doped source and drain regions, and a channel region provided therebetween. An insulating layer is formed on the polycrystalline silicon film 14. Contact holes for contacts with overlying source electrode and drain electrode are provided in insulation layer portions corresponding to the source and drain regions.

The present invention is applicable to the method for fabricating the polycrystalline silicon film 14 serving as the polycrystalline silicon active layer when the TFT is fabricated. In detail, the polycrystalline silicon active layer of the present invention is fabricated by forming the light absorption layer 12 on the surface of the substrate 10, and heating the light absorption layer 12 using light irradiation while vapor depositing the polycrystalline silicon film 14 on the light absorption layer 12.

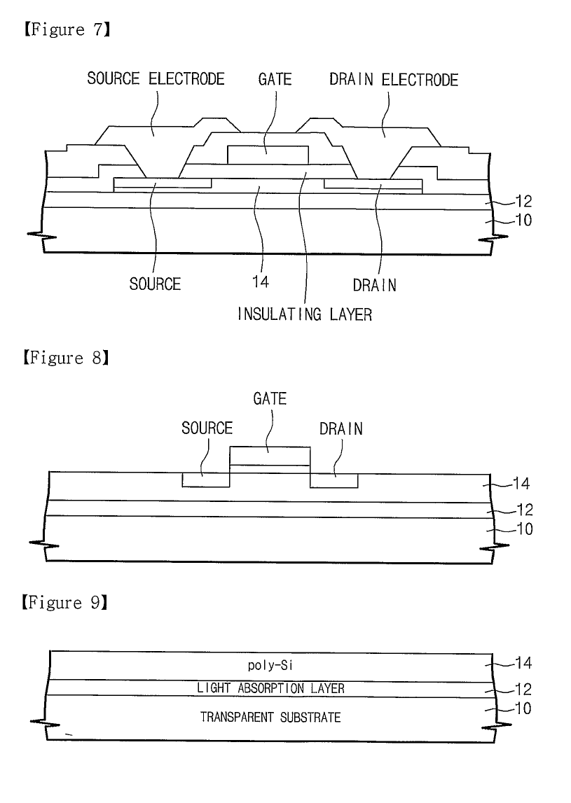

FIG. 8 is a cross section schematically illustrating a Field Effect Transistor (FET) according to the present invention. The FET includes a substrate 10; a light absorption layer 12 formed on the substrate 10; a polycrystalline silicon film 14 formed on the light absorption layer 12; a gate insulating layer formed on the polycrystalline silicon film 14; and a gate formed on the gate insulating layer. Source and drain regions are formed at both sides of the gate. The polycrystalline silicon film 14 serves as a polycrystalline silicon active layer.

The present invention is applicable to the method for fabricating the polycrystalline silicon film 14 serving as the polycrystalline silicon active layer, when the FET is fabricated. In detail, the polycrystalline silicon active layer of the present invention is fabricated by forming the light absorption layer 12 on a surface of the substrate 10, and heating the light absorption layer 12 using light irradiation while vapor depositing the polycrystalline silicon film 14 on the light absorption layer 12.

FIG. 9 is a cross section illustrating a structure of the polycrystalline silicon film according to the present invention. The light absorption layer 12 and the polycrystalline silicon film 14 are sequentially deposited on the transparent substrate 10.

The transparent substrate 10 is of glass or plastic.

The light absorption layer 12 is formed on the substrate 10. As described above, the light absorption layer 12 can be of material selected from the groups consisting of silicon (Si), amorphous silicon (a-Si), germanium (Ge), silicon carbide (SiC), amorphous carbon (a-C), gallium arsenide (GaAs), and silicon germanium (SiGe), and can be of III-V group compound semiconductor material.

The polycrystalline silicon film 14 is formed on the light absorption layer 12.

The structure of the polycrystalline silicon film 14, which is one of constituent elements of an electronic device, is also applicable to Thin Film Transistor Liquid Crystal Display (TFT LCD), Low Temperature PolySilicon (LTPS)-TFT LCD, Organic Light Emitting Diode (OLED), a solar cell, and other appliances needing the polycrystalline silicon film on the transparent substrate.

### INDUSTRIAL APPLICABILITY

As described above, the present invention has an advantage in that the RTP light source can be used as the energy source for depositing the polycrystalline silicon, not the heat treatment source, thereby fabricating the polycrystalline silicon having the excellent electrical characteristic.

Also, the present invention is advantageous of overcoming the vulnerability of the transparent substrate to a high temperature process and fabricating the polycrystalline silicon having the excellent electrical characteristic on the transparent substrate, by using the light absorption layer suppressing the transmittance of light through the transparent substrate of glass or plastic, and the substrate holder providing the backside cooling.

Also, the present invention is advantageous in cost aspect because the polycrystalline silicon of good quality is formed on the transparent substrate of cheap glass or plastic.

While the present invention has been described with reference to exemplary embodiments thereof, it will be apparent to those skilled in the art that various modifications can be made therein without departing from the spirit and scope of the invention as defined by the appended claims and their equivalents.

1. A method for fabricating a polycrystalline silicon film using a transparent substrate, the method comprising:
forming a light absorption layer on a surface of the transparent substrate; and
heating the light absorption layer using irradiation of Rapid Thermal Process (RTP) light source, while depositing the polycrystalline silicon film on the light absorption layer.

2. The method according to claim 1, further comprising performing backside cooling for controlling an increase of a temperature of the transparent substrate while forming the polycrystalline silicon film.

3. The method according to claim 1, wherein the light absorption layer is of any one selected from the groups consisting of silicon (Si), amorphous silicon (a-Si), germanium (Ge), silicon carbide (SiC), amorphous carbon (a-C), gallium arsenide (GaAs), silicon germanium (SiGe), and III-V group compound semiconductor material.

4. The method according to claim 1, wherein the light absorption layer is maintained at a spontaneous temperature within a range of 450° C. to 1600° C.

5. An apparatus for forming a polycrystalline silicon film on a surface of a transparent substrate, the apparatus comprising:
a substrate holder provided within a reaction furnace, and holding the transparent substrate and performing backside cooling for the transparent substrate;
the transparent substrate having a light absorption layer and loaded on the substrate holder; and
an RTP light source for heating the light absorption layer, and providing a reaction energy for forming the polycrystalline silicon film.

6. The apparatus according to claim 5, wherein the substrate holder further comprises a reflective film coated thereon.

7. The apparatus according to claim 5, wherein a process pressure within the reaction furnace is maintained within a range of 0.1 Torr to 1000 Torr.

8. The apparatus according to claim 5, wherein the substrate holder controls the backside cooling within a range of −20° C. to a substrate deformation temperature.

9. A method for fabricating a Thin Film Transistor (TFT) having a transparent substrate, a polycrystalline silicon active layer formed on the transparent substrate, a gate insulating layer formed on the polycrystalline silicon active layer, and a gate formed on the gate insulating layer,
wherein the forming of the polycrystalline silicon active layer further comprises:
forming a light absorption layer on a surface of the transparent substrate; and
heating the light absorption layer using irradiation of a Rapid Thermal Process (RTP) light source, while depositing a polycrystalline silicon film on the light absorption layer.

10. The method according to claim 9, wherein the light absorption layer is of any one selected from the groups consisting of silicon (Si), amorphous silicon (a-Si), germanium (Ge), silicon carbide (SiC), amorphous carbon (a-C), gallium arsenide (GaAs), silicon germanium (SiGe), and III-V group compound semiconductor material.

11. A method for fabricating a Field Effect Transistor (FET) having a transparent substrate, a polycrystalline silicon active layer formed on the transparent substrate, a gate insulating layer formed on the polycrystalline silicon active layer, and a gate formed on the gate insulating layer,
wherein the forming of the polycrystalline silicon active layer further comprises:
forming a light absorption layer on a surface of the transparent substrate; and
heating the light absorption layer using irradiation of an RTP light source, while depositing a polycrystalline silicon film on the light absorption layer.

12. The method according to claim 11, wherein the light absorption layer is of any one selected from the groups consisting of silicon (Si), amorphous silicon (a-Si), germanium (Ge), silicon carbide (SiC), amorphous carbon (a-C), gallium arsenide (GaAs), silicon germanium (SiGe), and III-V group compound semiconductor material.

13. A structure of a polycrystalline silicon film using a transparent substrate, the structure comprising:
a light absorption layer formed on the transparent substrate; and
the polycrystalline silicon film formed on the light absorption layer while heating the light absorption layer using irradiation of an RTP light source.

14. The structure according to claim 13, wherein the light absorption layer is of any one selected from the groups consisting of silicon (Si), amorphous silicon (a-Si), germanium (Ge), silicon carbide (SiC), amorphous carbon (a-C), gallium arsenide (GaAs), silicon germanium (SiGe), and III-V group compound semiconductor material.
